(19) United States
(12) Patent Application Publication
(10) Pub. No.: US 2006/0183290 A1
(43) Pub. Date: Aug. 17, 2006

(54) Manufacturing method for semiconductor device and rapid thermal annealing apparatus

(75) Inventors: Hiroyuki Kamada, Osaka-shi (JP); Keita Uchiyama, Takatsuki-shi (JP)

Correspondence Address: STEVENS, DAVIS, MILLER & MOSHER, LLP, 1615 L. STREET N.W., SUITE 850, WASHINGTON, DC, 20036, US

(73) Assignee: MATSUSHITA ELECTRIC INDUSTRIAL CO., LTD., Osaka (JP)

(21) Appl. No.: 11/324,806

(22) Filed: Apr. 11, 2006

(30) Foreign Application Priority Data
Jan. 6, 2005 (JP) 2005-001085

(51) Int. Cl. H01L 21/336

(52) U.S. Cl. 438/300

(57) ABSTRACT

During a manufacturing process for a semiconductor device, the size of gate electrodes is measured within the wafer surface. The gained measurement data is compared with the data which depends on the gate length-electrical properties of the semiconductor elements, and thus, distribution in the electrical properties within the wafer surface is expected. Next, the difference between the expected data on the electrical properties and the designed value is calculated, and this difference is compared with the data which depends on the temperature-electrical properties, so that the electrical property values a reconverted to temperature values. Next, the temperature distribution within the surface which makes inconsistency in said electrical properties within the surface minimal is determined from the gained data on the temperature distribution within the surface and the data on the temperature distribution within the surface which is gained from the equipment management data of the thermal annealing apparatus.

### BACKGROUND OF THE INVENTION

1. Field of the Invention

The present invention relates to a manufacturing method for a semiconductor device and a rapid thermal annealing apparatus. In particular, the present invention relates to a manufacturing method for a semiconductor device where inconsistency in the electrical properties of the semiconductor devices within a wafer surface caused by inconsistency in the processing within the wafer surface which occurs during the manufacturing process for a semiconductor device is minimized, as well as to a rapid thermal annealing apparatus.

2. Prior Art

Together with recent rapid miniaturization of devices and increase in the diameter of wafers, inconsistency in the processing which occurs during the manufacturing process for semiconductor devices (for example, inconsistency in the size of gates within a wafer surface and inconsistency in the temperature within the wafer surface at the time of RTA (rapid thermal annealing)) has come to greatly affect inconsistency in the electrical properties of the semiconductor devices. In addition, a problem arises, such that this reduces yield in the manufacture of semiconductor devices and lowers reliability.

A good method for solving this problem is to reduce inconsistency within a wafer surface which occurs in each piece of manufacturing equipment. Together with the miniaturization of devices, however, the tolerable amount of inconsistency in the processing has become smaller, and in actual circumstances, the performance of the manufacturing equipment has not met with this.

Therefore, a so-called feed forward technique has started being newly introduced, where inconsistency in the electrical property values of semiconductor devices, such as the threshold voltage (Vth) and the saturated current (Ids) of the finally gained transistors is reduced on the basis of data on inconsistency in the processing that has occurred in one step by determining the conditions for processing in subsequent steps (see, for example, Patent Documents 1 and 2).

Patent Document 1 discloses a manufacturing method where the gate length of the gate electrodes is measured and the dose of implanted ions for forming source and drain regions is set so as to vary in accordance with the measured value of the above described gate length, so that the properties of the transistors become of a predetermined level, in terms of short channel effects.

Patent Document 2 discloses a manufacturing method where the film forming conditions for coating films such as silicon nitride films, silicon oxide nitride films and the like, which coat semiconductor devices, as well as the conditions for the film thickness and composition components are automatically determined on the basis of the results of examination of electrical properties of the formed semiconductor devices in reference to database, and coating films are formed under the determined conditions.

Patent Document 1: Japanese Unexamined Patent Publication 2001-196580

Patent Document 2: Japanese Unexamined Patent Publication 2001-332723

These methods, however, have the following problems. First, in accordance with the method of Patent Document 1, it is possible to implant ions in different doses for each wafer in the case where a sheet fed type implanting machine is utilized. It is very difficult, however, to implant ions in different doses within a wafer surface for gates having different sizes which are generated within the wafer surface.

In addition, in accordance with the method of Patent Document 2, it is possible to change the film thickness and composition components for each wafer so as to change stress in the films, in the case where a sheet fed type film forming apparatus is utilized. However, it is very difficult to control the stress in the films within a wafer surface in response to inconsistency in the electrical properties of the semiconductor devices which occurs within the wafer surface. In addition, even in the case where the stress in the films within a wafer surface can be controlled, it is expected that the etching rate differs within the wafer surface due to the difference in the film composition. Therefore, it is believed that there is a high possibility that this affects the formation of microscopic contact holes.

Accordingly, though control of each wafer is possible in accordance with either method, it can be seen that these methods are not appropriate for controlling inconsistency in the electrical properties of the semiconductor devices which is caused by inconsistency in the processing which occurs within a wafer surface.

Furthermore, as a result of simulation to see to what extent inconsistency in each step affects the threshold voltage (Vth) and the saturated current (Ids) of recent microscopic semiconductor devices, it has been found that inconsistency in the gate length and in the temperature for activating RTA after the formation of sources and drains has a great effect.

### SUMMARY OF THE INVENTION

The present invention is provided in order to solve the above described problems, and an object thereof is to provide a manufacturing method for a semiconductor device where inconsistency in the electrical property values of the semiconductor devices within a wafer surface can be minimized, as well as a rapid thermal annealing apparatus.

In order to solve the above described problem, in accordance with a manufacturing method for a semiconductor device according to the present invention, inconsistency in the electrical property values of the finally gained semiconductor devices within a wafer surface is expected, and temperature distribution within a wafer surface during a thermal annealing process after the doping of impurities is controlled so that the inconsistency in the electrical property values of the semiconductor devices within the wafer surface becomes minimal, on the basis of the distribution of physical quantities within the wafer surface which have a correlation with the electrical property values of the semiconductor devices and are gained during the manufacturing process for the semiconductor devices, and data on temperature distribution within the wafer surface which is gained from the equipment management data of a thermal annealing apparatus that is used to activate impurities after the doping of the impurities.

According to this manufacturing method, inconsistency in the electrical property values of the finally gained semiconductor devices within a wafer surface can be minimized, and thus, it becomes possible to provide semiconductor devices of which the quality is uniform.

In accordance with the above described manufacturing method for a semiconductor device, it is preferable for an expected value that is gained as a result of expectation of inconsistency of the electrical property values of the semiconductor devices within the wafer surface to be converted to a table of temperature offset within the wafer surface for correcting the inconsistency of the electrical property values of the semiconductor devices within the wafer surface, and for the temperature distribution of the thermal annealing process after the doping of the impurities within the wafer surface to be determined on the basis of the table of the temperature offset within the wafer surface and the data on temperature distribution within the wafer surface that is gained from the equipment management data of the thermal annealing apparatus.

In addition, in accordance with the manufacturing method for a semiconductor device according to the present invention, the above described manufacturing method for a semiconductor device comprises the step of measuring the electrical properties of semiconductor devices after the thermal annealing process, wherein temperature distribution within the wafer surface is calculated from the difference between the measurement results and the designed value of the electrical properties of the semiconductor devices, and the data on temperature distribution within the wafer surface of the thermal annealing apparatus is updated so as to correct the temperature distribution.

According to this manufacturing method, temperature distribution data within a wafer surface in the thermal annealing apparatus is always updated, and inconsistency in the temperature caused by the apparatus can be reduced. As a result, the precision of the expected values of inconsistency within a surface of the electrical property values of the semiconductor devices increases.

Furthermore, in accordance with the manufacturing method for a semiconductor device according to the present invention, the above described manufacturing method for a semiconductor device comprises the steps wherein the difference between the highest temperature and the lowest temperature in the wafer surface is calculated after the calculation of the temperature distribution within the wafer surface, and when this difference exceeds a certain value, an alarm indicating an abnormality in the process is generated at this point in time.

According to this manufacturing method, it becomes possible to detect abnormality in the process which is not noticeable in a conventional manufacturing process. In addition, in the case where there is a difference in the temperature of no less than a certain value within a wafer surface at the time of the thermal annealing, there is a risk that a slip may occur in the wafer, and this manufacturing method can prevent this. Here, slip is the local slip of a crystal surface on a semiconductor substrate, caused by thermal stress or the like at the time of thermal annealing. A shift in the alignment may occur in the vicinity of the portion where such a slip has occurred when exposed to light, and this may lead to reduction in the yield of the manufacture of the devices.

In accordance with the above described manufacturing method for a semiconductor device, the physical quantities are measured values which are gained through measurement of size or measurement of film thickness, which are carried out in order to confirm how processing was carried out after the processing during, for example, the manufacturing process. In addition, any one of the threshold voltage (Vth) of a PMOS transistor, the saturated current (Ids) of the PMOS transistor and the non-silicide resistance of a PD region, for example, is measured as the electrical properties of the semiconductor devices. In addition, the impurities are impurities which are doped into, for example, source and drain regions of the semiconductor devices. In addition, the thermal annealing is RTA (rapid thermal annealing) that is carried out in, for example, a rapid thermal annealing apparatus. In addition, it is preferable for the difference in the temperature which allows an alarm indicating an abnormality in the process to be generated (constant value) to be no higher than 20° C. In addition, it is preferable for the thermal annealing to be carried out between 900° C. to 1200° C.

The above described PD region indicates a portion into which P type impurities are doped at the time of the formation of the sources and drains of P channel transistors. In the above description, measurement is carried out in the PD region instead of an ND region (portion into which N type impurities are doped) for the following reasons. That is to say, it is known from experiment that fluctuation in the properties of the PD region in response to the fluctuation in the temperature at the time of thermal annealing which is carried out according to the present invention is sensitive in comparison with that of the ND region.

A rapid thermal annealing apparatus according to the present invention is provided with a stage for supporting a wafer, a heat source for heating the wafer for each zone, a thermometer for measuring the temperature of the wafer for each zone, a temperature controller for taking in temperature information from the thermometer and calculating the output value of the heat source for each zone, a driver for making the heat source output for each zone in accordance with the set output value from the temperature controller, and a process control system for providing data on temperature distribution which indicates temperature distribution within a wafer surface at the time of thermal annealing and is the control target for the wafer for each zone to the temperature controller. Thus the process control system expects inconsistency in the electrical property values of the finally gained semiconductor devices within a wafer surface, and generates temperature distribution data showing the temperature distribution within a wafer surface so that the inconsistency in the electrical property values of the semiconductor devices within the wafer surface becomes minimal as the temperature distribution data showing the temperature distribution within the wafer surface at the time of the thermal annealing process on the basis of the distribution of physical quantities within the wafer surface which have a correlation with the electrical property values of the semiconductor devices and are gained during the manufacturing process for the semiconductor devices, and data on temperature distribution within the wafer surface which is gained from the equipment management data of a thermal annealing apparatus that is used to activate impurities after the doping of the impurities, and thereby, temperature distribution within a wafer surface which makes inconsistency in the electrical property values of the semiconductor devices within the wafer surface minimal in the thermal annealing process for activating impurities after the doping of the impurities is gained.

This configuration makes it possible to implement a manufacturing method for a semiconductor device as that described above.

In the above described rapid thermal annealing apparatus, it is preferable for an expected value that is gained as a result of expectation of inconsistency of the electrical property values of the semiconductor devices within the wafer surface to be converted to a table of temperature offset within the wafer surface for correcting the inconsistency of the electrical property values of the semiconductor devices within the wafer surface, and for the data on temperature distribution within the wafer surface at the time of thermal annealing to be determined on the basis of the table of the temperature offset within the wafer surface and the data on temperature distribution within the wafer surface that is gained from the equipment management data of the thermal annealing apparatus.

In the above described rapid thermal annealing apparatus, it is preferable for the temperature controller to carry out electrical property measurement on the semiconductor devices after the thermal annealing process, calculate the temperature distribution within the wafer surface from the difference between the measurement results and the designed value of the electrical properties of the semiconductor devices, and control the output value of the heat source so as to correct the temperature distribution.

In addition, in the above described rapid thermal annealing apparatus, the physical quantities are measured values which are gained through measurement of size or measurement of film thickness, which are carried out in order to confirm how processing was carried out after the processing during, for example, the manufacturing process. In addition, the impurities are impurities which are doped into, for example, source and drain regions of the semiconductor devices. In addition, it is preferable for the thermal annealing to be carried out between 900° C. to 1200° C. In addition, it is preferable for the heat source for heating a wafer to be, for example, a lamp having a wavelength ranging from visible to infrared. In addition, it is preferable for the thermometer for measuring the temperature of a wafer to be a non-contact type pyrometer that is installed on the rear surface of the wafer, or a thermocouple that makes contact with the rear surface of the wafer. In addition, it is preferable for a heat source which is placed on the front surface of a wafer and a thermometer which is placed on the rear surface of the wafer to correspond one-to-one through a temperature controller for taking in information from the thermometer and calculating the output value of the heat source, and through a driver for making the heat source output. In addition, it is preferable for the heat source and the thermometer to share the same alignment, and for the thermometer to be placed directly beneath the heat source. In addition, it is preferable for the wafer not to rotate.

As described above, according to the present invention, it becomes possible to minimize inconsistency in the electrical properties of semiconductor devices that is caused by inconsistency in the processing within a wafer surface which occurs during the manufacturing process for semiconductor devices. As a result of this, semiconductor devices of which the quality is uniform can be provided within a wafer surface. In addition, according to the present invention, it becomes possible to minimize inconsistency in the electrical properties within a wafer surface.

### BRIEF DESCRIPTION OF THE DRAWINGS

FIG. 1 is a flow chart illustrating a manufacturing method for a semiconductor device according to the first embodiment of the present invention;

FIGS. 2A, 2B and 2C are cross sectional diagrams illustrating the semiconductor device during the manufacturing process in accordance with the manufacturing method for a semiconductor device according to the first embodiment of the present invention;

FIG. 3 is a diagram illustrating a method for converting distribution in the gate size within a surface into distribution in the electrical properties of the semiconductor device within a surface in accordance with the manufacturing method for a semiconductor device according to the first embodiment of the present invention;

FIG. 4 is a diagram illustrating data on distribution in the difference between the electrical property values of the semiconductor device and the designed values within a surface in accordance with the manufacturing method for a semiconductor device according to the first embodiment of the present invention;

FIG. 5 is a diagram illustrating a method for converting data on distribution in the difference between the electrical property values of the semiconductor device and the designed values within a surface into distribution in the temperature in accordance with the manufacturing method for a semiconductor device according to the first embodiment of the present invention;

FIG. 6 is a diagram for illustrating a method for determining the distribution in the temperature within a wafer surface which minimizes inconsistency in the electrical property values of the semiconductor device within the surface in accordance with the manufacturing method for a semiconductor device according to the first embodiment of the present invention;

FIG. 7 is a flow chart illustrating a manufacturing method for a semiconductor device according to the second embodiment of the present invention;

FIG. 8 is a flow chart illustrating a manufacturing method for a semiconductor device according to the third embodiment of the present invention; and

FIG. 9 is a schematic diagram showing a semiconductor manufacturing apparatus according to the fourth embodiment of the present invention.

### DESCRIPTION OF PREFERRED EMBODIMENTS

### First Embodiment

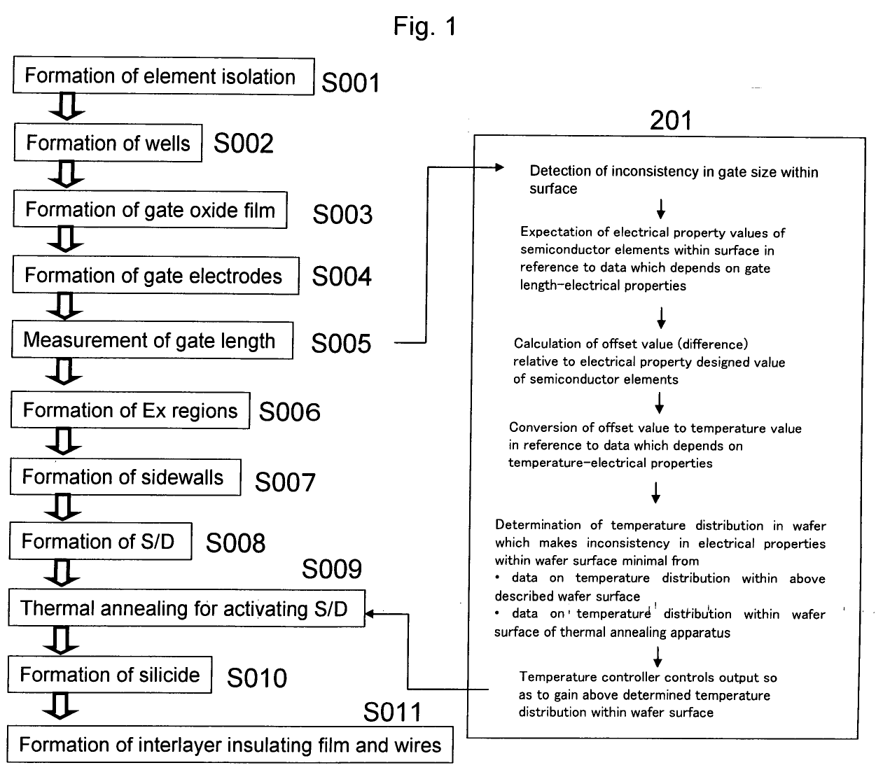

In the following, an embodiment of the present invention is described in reference to FIGS. 1, 2A to 2C, 3, 4, 5 and 6.

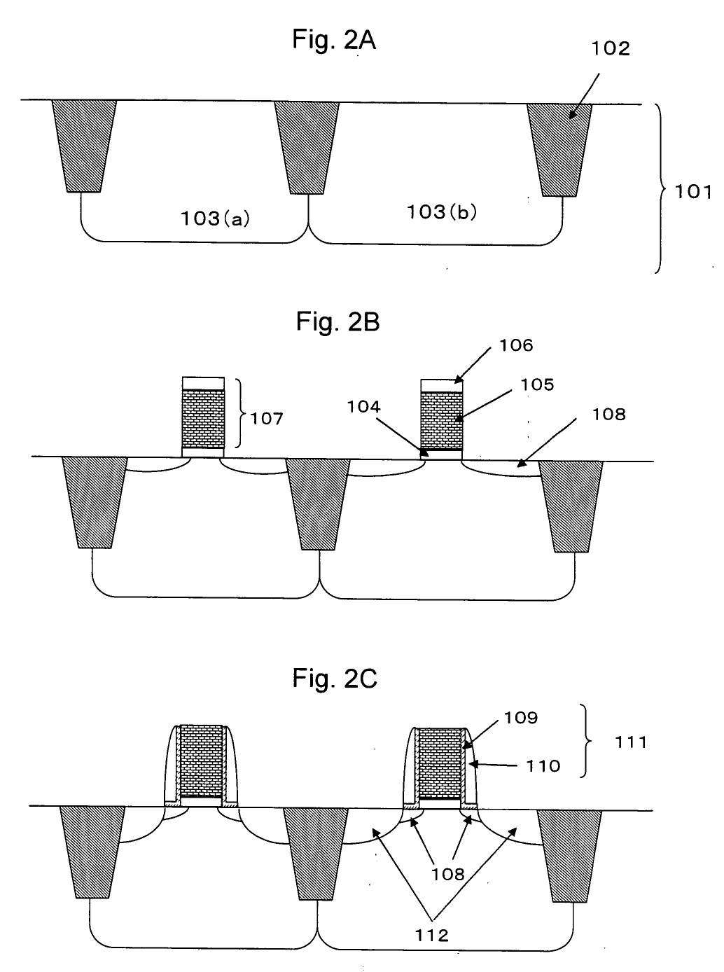

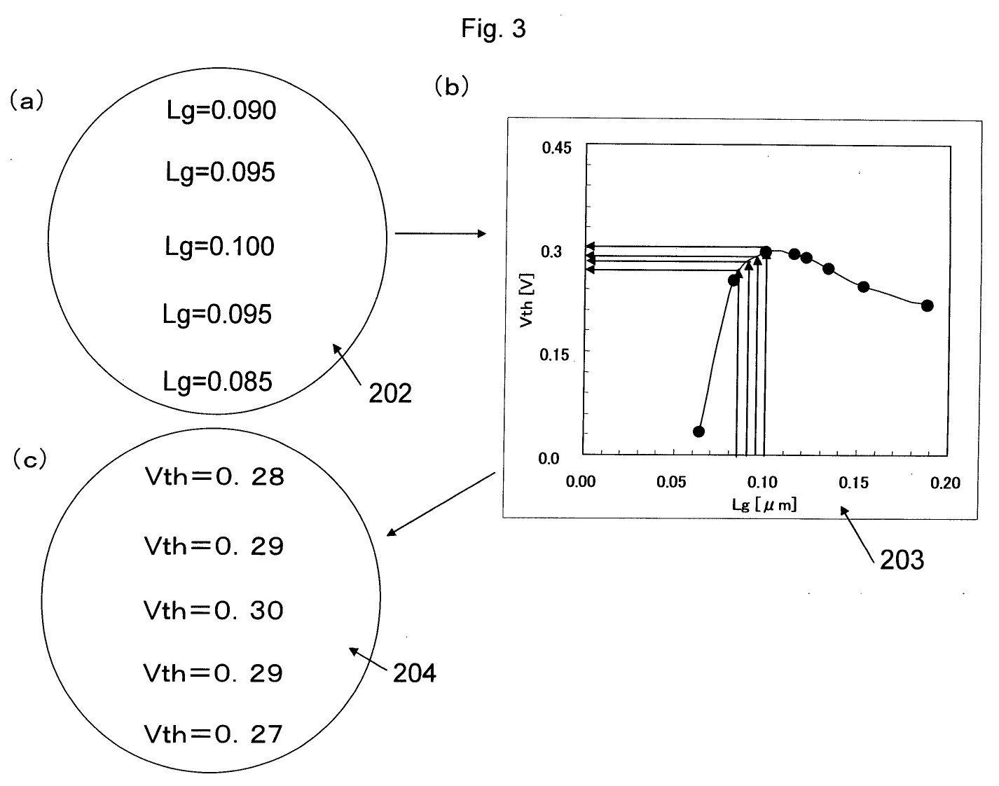

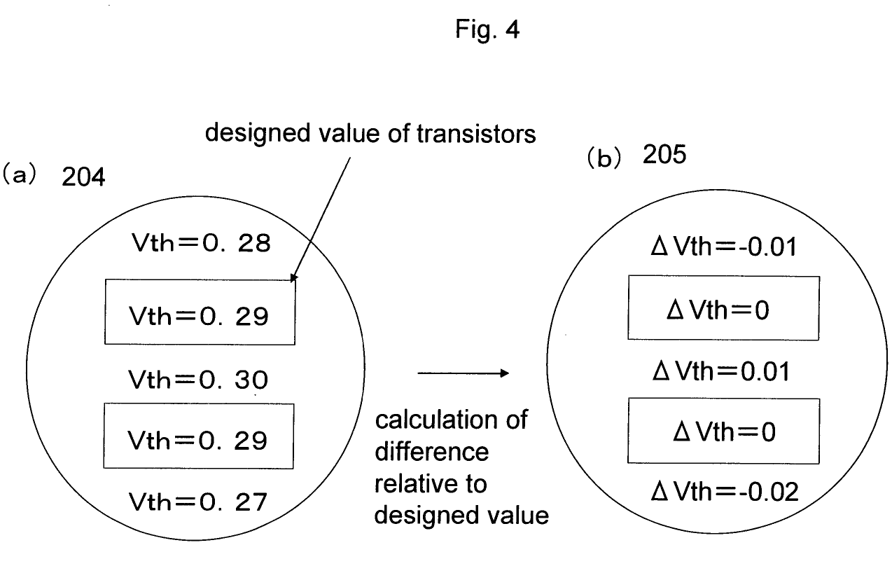

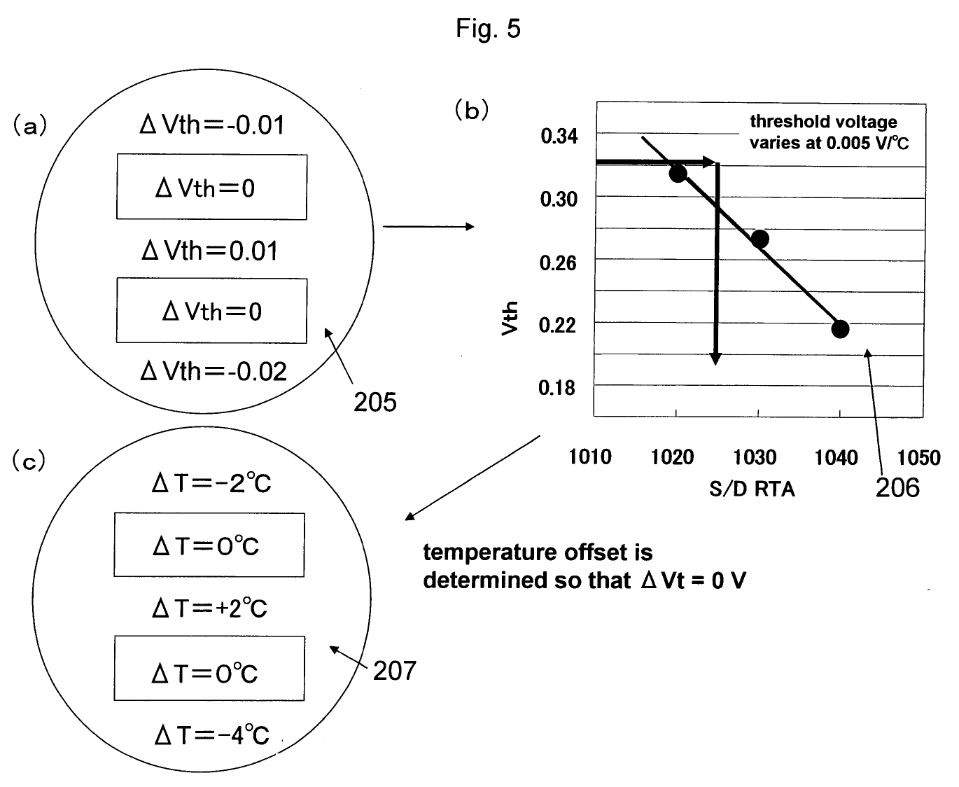

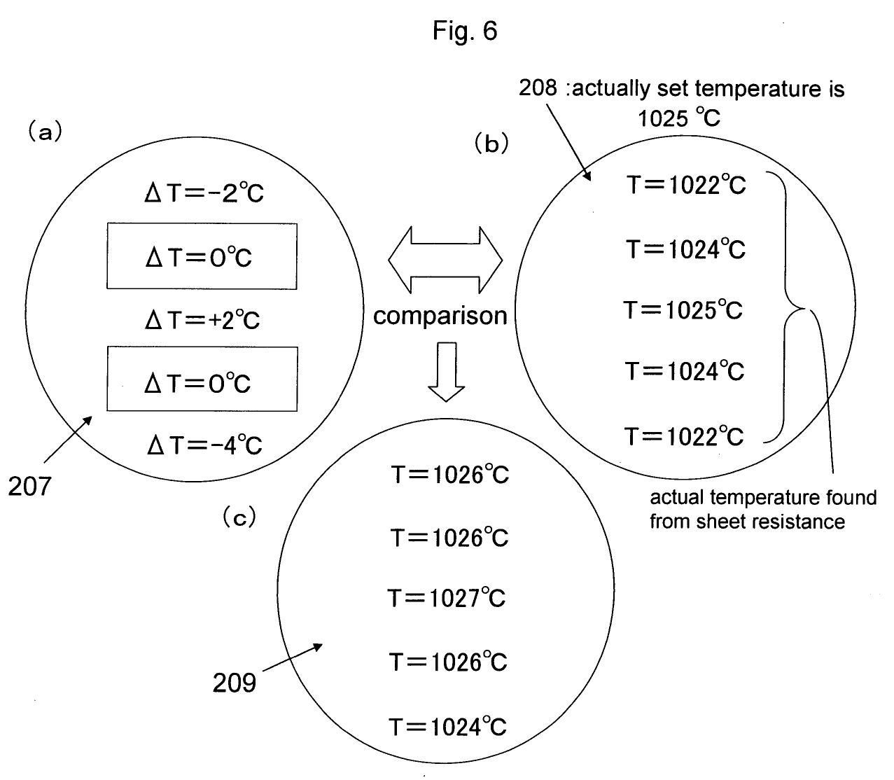

FIG. 1 is a flow chart illustrating a manufacturing method for a semiconductor device according to the present invention. FIGS. 2A, 2B and 2C are cross sectional diagrams illustrating the manufacturing steps for a semiconductor device. FIG. 3 is a diagram illustrating a method for converting distribution in the gate size within a surface that has been gained in Step S005 into distribution in the electrical properties of the semiconductor device within a surface. FIG. 4 is a diagram illustrating data on distribution in the difference between the electrical property values of the semiconductor device and the designed values within a surface. FIG. 5 is a diagram illustrating a method for converting data on distribution in the difference between the electrical property values of the semiconductor device and the designed values within a surface into distribution in the temperature. FIG. 6 is a diagram for illustrating a method for determining the distribution in the temperature within a wafer surface which minimizes inconsistency in the electrical property values of the semiconductor device within the surface.

First, as shown in FIG. 1, an element isolation 102 is formed on a silicon substrate 101 in Step S001 (FIG. 2A), and after that, a P well 103a and an N well 103b are formed in accordance with a photolithographic process and an implantation process in Step S002.

Next, in Step S003, a gate oxide film 104 is formed on the surface of silicon substrate 101 in accordance with a thermal oxidation method (FIG. 2B), and furthermore, a non-doped polysilicon film 105 is deposited. After that, boron (B) is doped into a PMOS forming region, and phosphorous (P) is doped into an NMOS forming region in accordance with a photolithographic process and an implantation process. Furthermore, a first TEOS film 106 is deposited on polysilicon film 105.

Next, in Step S004, gate electrodes 107 are formed in accordance with a photolithographic process and a dry etching process.

Next, in Step S005, the distribution in the size (gate length) Lg of gate electrodes 107 within the wafer surface is measured. The measured distribution data within the wafer surface 202 (FIG. 3(a)) is transmitted to a process control system 201.

Here, a method for determining the distribution in the temperature within the wafer surface, which minimizes inconsistency in the electrical property values of the finally gained semiconductor device within the surface from the distribution in gate size Lg within the wafer surface that has been sent to process control system 201 is described. Here, in the present embodiment, the designed value of the threshold voltage (Vth) of the transistors is 0.29 V.

First, as shown in FIG. 3, data 202 on the distribution in the transmitted gate size Lg within the wafer surface is compared with data 203 which depends on the gate length (Lg)-electrical properties (threshold voltage Vth) that have been acquired in advance (FIG. 3(b)), and thereby, is converted to data 204 on distribution in the electrical property values (threshold voltage Vth) of the semiconductor elements within the surface (FIG. 3(c)). This data 204 on the distribution within the surface is the expected value of the threshold voltage (Vth).

Here, a method for acquiring data 203 which depends on the gate length (Lg)-electrical properties (threshold voltage Vth) of FIG. 3(b) is described. A pattern where gate sizes vary is provided within a TEG (test element group), and this portion is measured, and thereby, the data which depends on the gate length (Lg)-electrical properties (threshold voltage Vth) is acquired. At this time, it is expected that the actual size is different from the designed value (mask size), and therefore, the size of the gate after etching in the corresponding pattern is measured in advance, in order to confirm the actual size, and this value is taken along the lateral axis of the graph of FIG. 3(b). In addition, a number of portions are measured within the wafer surface, so that the gate length (Lg) and the threshold voltage (Vth) are both represented by the average value. Here, the above described data 203 which depends on the gate length (Lg)-electrical properties (threshold voltage Vth) is acquired under the condition of a constant temperature (1025° C.).

Next, as shown in FIG. 4, the difference between the above described distribution data 204 within the surface (FIG. 4(a)) and the designed value of the threshold voltage (Vth) of the transistors is taken and converted to the distribution data 205 of the difference relative to the designed value within the surface (FIG. 4(b)).

Next, as shown in FIG. 5, temperature offset is determined from the above described distribution data 205 within the surface (FIG. 5(a)), and the data 206 which depends on the temperature-electrical properties (threshold voltage Vth) that has been acquired in advance (FIG. 5(b)), so that the threshold voltage (Vth) of the transistors becomes the same as the designed value. In the present embodiment, for example, the temperature corresponds to 1025° C. in the case of Vth=0.29 V, and the temperature corresponds to 1023° C. in the case of Vth=0.30 V. Therefore, it is necessary to set a temperature which is higher by 1025-1023=2° C. for the portion where Vth=0.30 V is expected. In this manner, a table 207 of temperature offset within the wafer surface is prepared (FIG. 5(c)).

Here, a method for acquiring data 206 which depends on the temperature-electrical properties (threshold voltage Vth) (FIG. 5(b)) is described. A process for changing the processing temperature for each wafer is carried out. At this time, distribution in the temperature within the wafer surface is constant, and only the center value is changed. After the completion of diffusion, transistors having the same size which are placed in, for example, scribe PCM (process control monitor) are measured so as to acquire the data which depends on the temperature-electrical properties. The average value for the electrical properties, for example, the threshold voltage (Vth), is gained by measuring a number of portions within the wafer surface. At this time, there is a possibility that the gate size may differ between wafers, and therefore, it is necessary for the gate size of the transistors in the corresponding portions to be measured in advance after etching, and for correction to be carried out in accordance with FIG. 3(b). Here, the temperature and the gate size independently affect the electrical properties, and therefore, no problem arises, even if correction is carried out.

Finally, as shown in FIG. 6, the above described temperature offset table 207 (FIG. 6(a)) and data 208 on temperature distribution within the wafer surface that is gained from the equipment management data of the thermal annealing apparatus (FIG. 6(b)) are compared. Here, the above described data 208 on temperature distribution within the wafer surface provides actual temperatures of the wafer which are gained from the results of measuring sheet resistance when all of the portions are set at the same temperature (1025° C. in the present embodiment). In the present embodiment, it can be seen that the temperature of the portions toward the outer periphery of the wafer becomes lower than the set temperature by 1° C. to 3° C. Therefore, it is necessary to add this difference to the above described temperature distribution 206 within the wafer surface, in order to gain the temperature distribution within the wafer surface for the final processing. Concretely, it can be calculated from the following equation.
set temperature (1025° C.)−(difference between set temperature and actual temperature)+temperature offset

Data 209 on temperature distribution that is gained through this process (FIG. 6(c)) becomes the temperature distribution within the wafer surface which makes inconsistency in the electrical property values of the finally gained semiconductor device within the surface minimal.

These processes are instantly carried out in a microprocessor which is mounted on process control system 201.

Next, in Step S006, impurities are doped on both sides of gate electrodes 107 in accordance with a photolithographic process and an implantation process. Boron (B) is doped into the PMOS forming region, and arsenic (As) is doped into the NMOS forming region, so that extension (Ex) regions 108 are formed.

Next, in Step S007, a second TEOS film 109 and a silicon nitride film 110 are sequentially deposited on silicon substrate 101 (FIG. 2C), and after that, etch-back is carried out through anisotropic etching, so that sidewalls 111 are formed on the sides of gate oxide films 104 and gate electrodes 107. Furthermore, in Step S008, boron (B) is doped into the PMOS forming region, and arsenic (As) and phosphorous (P) are doped into the NMOS forming region in accordance with a photolithographic process and an implantation process using the photoresist, gate electrodes 107 and sidewalls 111 as a mask. As a result, high concentration source and drain (S/D) regions 112 are formed outside of extension regions 108.

Next, in Step S009, the temperature controller controls the output so that temperature distribution 209 within the wafer surface that has been found in advance can be gained, and thermal annealing is carried out for approximately 10 seconds (source/drain (S/D) activating thermal annealing).

Finally, in Step S010, a silicide layer is formed on gate electrodes 107 and high concentration source and drain regions 112, and in Step S011, an interlayer insulating film, contact holes and wires are formed. As described above, a semiconductor device where inconsistency in the electrical properties within the wafer surface is prevented is formed.

Here, according to the present embodiment, a method for calculating temperature distribution within the wafer surface on the basis of distribution in the gate size within the wafer surface is described. However, temperature distribution within the wafer surface can be calculated in the same manner as above, from other physical quantities, such as the width of sidewalls, the film thickness of gate electrodes, other sizes and film thicknesses, in the case where the correlation between these and the temperature distribution within the wafer surface is known in advance.

Furthermore, according to the present embodiment, the threshold voltage (Vth) of transistors is used as electrical properties, and the correlation between the threshold voltage (Vth) of transistors and the gate length, as well as the temperature, is utilized. However, it is fine to adopt the saturated current (Ids) and the resistance value of transistors as these electrical properties.

Furthermore, it becomes possible to prevent inconsistency in the electrical properties of the finally gained semiconductor device within the wafer surface in the case where temperature distribution is calculated from a number of physical quantities and electrical property data.

In addition, though according to the present embodiment, calculation of the actual temperature of the wafer from the measurement results of the sheet resistance, which can be measured by carrying out thermal annealing after the doping of impurities into the silicon substrate, is utilized as the equipment management data of the thermal annealing apparatus, it is fine to use other physical quantities (for example, the thickness of oxide films) which correlate with the actual temperature of the wafer.

In addition, though according to the present embodiment, a temperature band in the vicinity of 1025° C. is used for the source and drain region activating thermal annealing, the above described means work effectively in a temperature band from 900° C. 1200° C.

### Second Embodiment

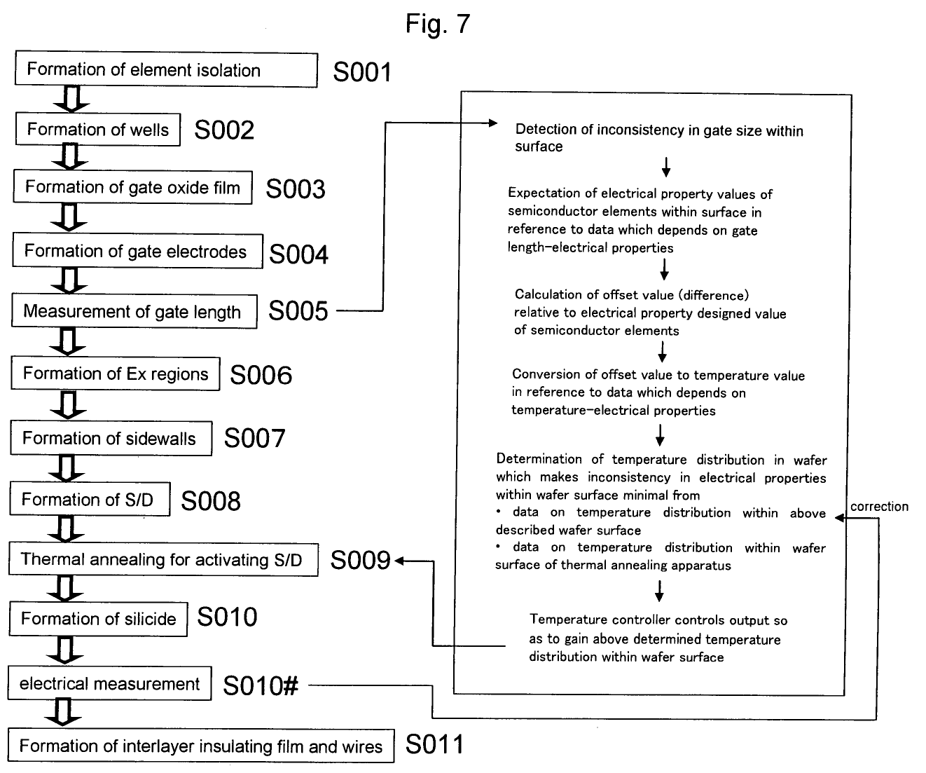

In the following, an embodiment of the present invention is described in reference to FIG. 7.

FIG. 7 is a flow chart illustrating another manufacturing method for a semiconductor device according to the present invention.

This embodiment is different from the first embodiment in that electrical measurement is inserted as Step S010# after the formation of silicide in Step S010, so that the results of measurement can be fed back to data 208 on the temperature distribution within the wafer surface in the equipment.

In the present step, the electrical properties of semiconductor elements are measured using a scribe PCM (press control monitor) pattern that is provided in order to confirm how the elements are made. Inconsistency in the electrical properties gained herein within the wafer surface corresponds only to inconsistency in the temperature of the thermal annealing apparatus in the case where the first embodiment is completely implemented. Therefore, the gained results of the electrical properties are converted to temperature distribution in the wafer in accordance with a method that is the same as the method shown in FIG. 5, so as to update data 208 on temperature distribution within the wafer surface in the equipment. This feedback is repeated, and thereby, inconsistent temperatures in the thermal annealing apparatus converge to a certain value, and thus, precision in temperature distribution 209 within the wafer surface which makes inconsistency in the electrical property values of the semiconductor devices within the surface minimal increases, and therefore, it becomes possible to prevent inconsistency in the electrical properties of the finally gained semiconductor device within the wafer surface.

Though the electrical properties are described in the present embodiment, it takes time to carry out electrical measurement on all of the PCM patterns, and thus, TAT (turnaround time) is prolonged. Therefore, it is preferable to measure any one of the threshold voltage (Vth) of the PMOS transistor, the saturated current (Ids) of the PMOS transistor and non-silicide resistance in the PD region, which are particularly sensitive to inconsistency in the temperature for thermal annealing after the formation of the sources and drains. In this manner, electrical measurement can be simplified.

### Third Embodiment

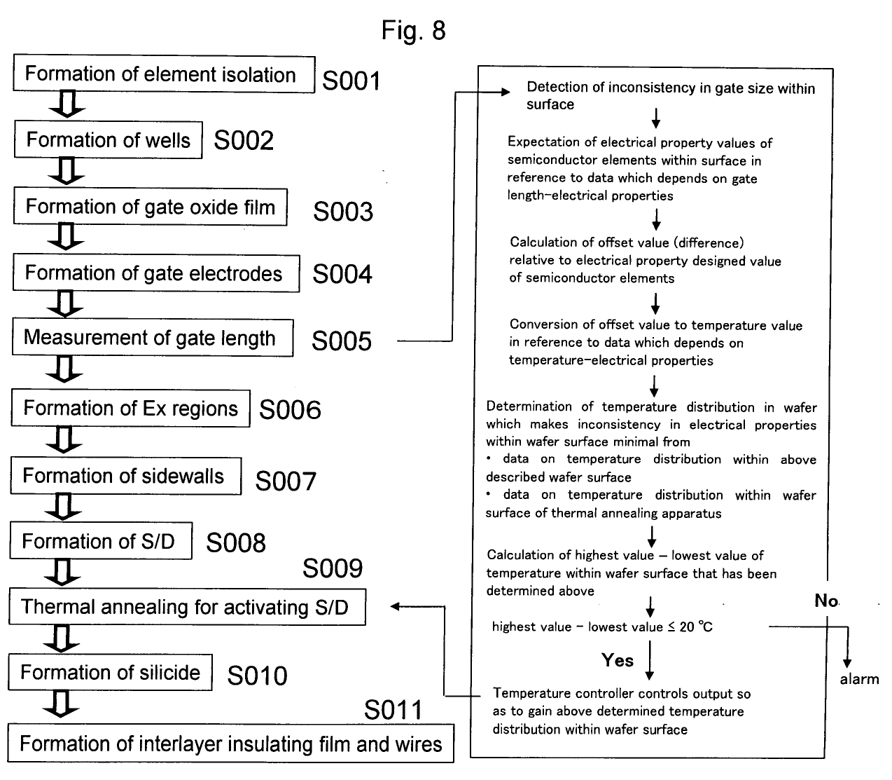

In the following, another embodiment of the present invention is described in reference to FIG. 8.

FIG. 8 is a flow chart illustrating a manufacturing method for a semiconductor device according to the present invention.

This embodiment is different from the first embodiment in that the difference between the highest temperature and the lowest temperature within the wafer surface is calculated after the calculation of temperature distribution 209 within the wafer surface, and when this difference exceeds a certain value (20° C. in the present embodiment), an alarm indicating an abnormality in the process is generated at this point in time.

If this alarm is issued, it can be assumed that some abnormality has occurred anywhere between Step S001 to Step S009, or an abnormality (deterioration of a lamp or the like) has occurred in the thermal annealing apparatus. As described above, it becomes possible to detect abnormalities in the process which are not noticeable in the conventional manufacturing process, so that defects in the process can be prevented. In addition, in the case where the difference in the temperature is no lower than a certain value within a wafer surface at the time of thermal annealing, there is a risk that a slip may occur in the wafer, and therefore, the alarm functions so as to prevent this.

The value for the difference in the temperature is 20° C. in the present embodiment, and it is preferable for the calculated difference in the temperature to be no higher than 20° C., because if the difference in the temperature within the wafer surface is great, a slip may occur in the silicon substrate, as described above, and the wafer may jump off from the wafer stage at the time of wafer processing.

### Fourth Embodiment

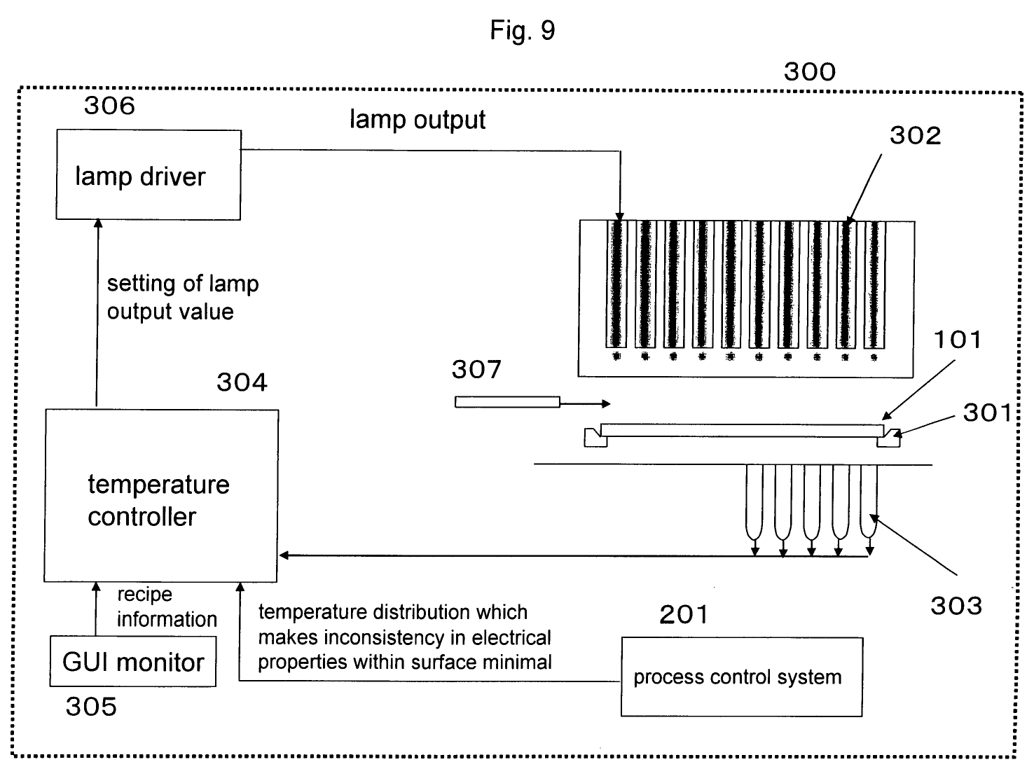

In the following, a concrete example of the configuration of the rapid thermal annealing apparatus 300 that is used in the above described first embodiment is described in reference to FIG. 9.

FIG. 9 is a schematic diagram showing a semiconductor manufacturing apparatus according to the present invention.

A silicon substrate 101 is supported on an edge ring 301. Tungsten halogen lamps 302 having a wavelength in a range from visible to infrared are placed in an array above silicon substrate 101 as a light energy source. In addition, temperature measurement is carried out in a non-contact manner by means of a pyrometer 303 which is placed on the rear surface of silicon substrate 101. Outlet 307 for a nitrogen gas is provided on the side of silicon substrate 101, and emits a nitrogen gas for efficiently conveying light energy that has been outputted from the lamps to silicon substrate (wafer) 101 at the time of thermal annealing.

In addition, a process control system 201 as that described above, a temperature controller 304 for controlling the temperature, a GUI monitor 305 where recipe information is stored, and a lamp driver 306 for making the lamps output in accordance with the lamp output set value that is received from temperature controller 304 are respectively connected via a network. In addition, tungsten halogen lamps 302 and lamp driver 306 are connected, so that independent control of the respective zones becomes possible.

Next, the operation of rapid thermal annealing apparatus 300, which is the semiconductor manufacturing apparatus of the present embodiment, is described.

First, silicon substrate 101 is conveyed onto edge ring 301.

Subsequently, recipe information (temperature information of each step) that is instructed by GUI monitor 305, and data 209 on temperature distribution that is described in the first embodiment are transmitted from process control system 201 to temperature controller 304.

Next, temperature controller 304 calculates the lamp output value in each zone taking the recipe information into account, so that temperature distribution within a wafer surface at the time of thermal annealing becomes the same as data 209 on temperature distribution that is described in the first embodiment, and instructs lamp driver 306.

Next, the instructed lamp driver 306 makes tungsten halogen lamp 302 in each zone output so as to heat the wafer.

At the time of the thermal annealing, pyrometer 303 that has been installed on the rear surface of silicon substrate 101 reads the processing temperature in each zone, and this data is transmitted to temperature controller 304. Temperature controller 304 controls the lamp output value at 100 Hz, so as to correct the difference relative to data 209 on temperature distribution.

Finally, the wafer where the thermal annealing is completed is cooled by a nitrogen gas on edge ring 301, and after that, conveyed out.

As described above, rapid thermal annealing apparatus 300 of this embodiment is provided with edge ring 301 for supporting silicon substrate 101, tungsten halogen lamps 302 for heating silicon substrate 101 for each zone, pyrometer 303 for measuring the temperature of silicon substrate 101 for each zone, temperature controller 304 for taking in temperature information from pyrometer 303 and calculating the output value of tungsten halogen lamps 302 for each zone, lamp driver 306 for making tungsten halogen lamps 302 output for each zone in accordance with the output set value from temperature controller 304, and process control system 201 for supplying temperature distribution data which indicates temperature distribution within a wafer surface at the time of thermal annealing and is the control target for silicon substrate 101 for each zone to temperature controller 304. In addition, process control system 201 expects inconsistency in the electrical property values of the finally gained semiconductor devices within a wafer surface from distribution of physical quantities which are gained during the manufacturing process for the semiconductor devices within a wafer surface, and data on temperature distribution within a wafer surface that is gained from the equipment management data of the thermal annealing apparatus, and generates temperature distribution data which indicates temperature distribution within the wafer surface that makes inconsistency in the electrical property values of the semiconductor devices within the wafer surface minimal as temperature distribution data which indicates temperature distribution within the wafer surface at the time of thermal annealing, and thereby, implements temperature distribution within the wafer surface in such a manner that inconsistency in the electrical property values of the semiconductor devices within the wafer surface becomes minimal in the thermal annealing process for activating impurities after the doping of the impurities.

In addition, temperature controller 304 carries out electrical property measurement on the semiconductor devices after the thermal annealing process, calculates temperature distribution within the wafer surface from the difference between the measurement results and the designed value of the electrical properties of the semiconductor devices, and controls the output value of tungsten halogen lamps 302 so that the temperature distribution thereof is corrected.

Though in the present embodiment, temperature measurement is carried out by a pyrometer, a measuring method where a thermocouple is made to make contact with the rear surface of a wafer may be used. In addition, any lamp other than tungsten halogen lamps may be used, as long as it can cover the wavelength region ranging from visible to infrared.

In addition, in the present embodiment, the relationship between the tungsten halogen lamps and the pyrometer (or thermocouple) is not described. However, tungsten halogen lamps and pyrometers (or thermocouples) may be aligned and placed so as to correspond one-to-one, in such a manner that temperature measurement is carried out by the pyrometer (or thermocouple) directly beneath a tungsten halogen lamp, in order to enhance temperature controllability within the wafer surface in a more effective manner. In addition, in the case of such alignment, it is preferable not to rotate a wafer, in order to implement desired temperature distribution, even the distribution is imbalanced within a wafer surface.

### INDUSTRIAL APPLICABILITY

A manufacturing method for a semiconductor device according to the present invention has effects such that inconsistency in the electrical property values of the semiconductor devices within a wafer surface can be minimized, and is useful as a method for forming a MOS type transistor.

What is claimed is:

1. A manufacturing method for a semiconductor device, wherein inconsistency in the electrical property values of the finally gained semiconductor devices within a wafer surface is expected, and temperature distribution within a wafer surface during a thermal annealing process after the doping of impurities is controlled so that the inconsistency in the electrical property values of said semiconductor devices within the wafer surface becomes minimal, on the basis of the distribution of physical quantities within the wafer surface which have a correlation with the electrical property values of the semiconductor devices and are gained during the manufacturing process for said semiconductor devices, and data on temperature distribution within the wafer surface which is gained from the equipment management data of a thermal annealing apparatus that is used to activate impurities after the doping of the impurities.

2. The manufacturing method for a semiconductor device according to claim 1, wherein
an expected value that is gained as a result of expectation of inconsistency of the electrical property values of said semiconductor devices within the wafer surface is converted to a table of temperature offset within the wafer surface for correcting the inconsistency of the electrical property values of said semiconductor devices within the wafer surface, and
the temperature distribution within the wafer surface during the thermal annealing process after said doping of the impurities is determined on the basis of said table of the temperature offset within the wafer surface and the data on temperature distribution within the wafer surface that is gained from the equipment management data of said thermal annealing apparatus.

3. The manufacturing method for a semiconductor device according to claim 1, comprising the step of measuring the electrical properties of semiconductor devices after the thermal annealing process, wherein temperature distribution within the wafer surface is calculated from the difference between the measurement results and the designed value of the electrical properties of said semiconductor devices, and the data on temperature distribution within the wafer surface of the thermal annealing apparatus is updated so as to correct the temperature distribution.

4. The manufacturing method for a semiconductor device according to claim 1, wherein the difference between the highest temperature and the lowest temperature in the wafer surface is calculated after the calculation of the temperature distribution within the wafer surface, and when this difference exceeds a certain value, an alarm indicating an abnormality in the process is generated at this point in time.

5. The manufacturing method for a semiconductor device according to claim 1, wherein the physical quantities are measured values which are gained through measurement of size or measurement of film thickness, which are carried out in order to confirm how processing was carried out after the processing during the manufacturing process.

6. The manufacturing method for a semiconductor device according to claim 3, wherein any one of the threshold voltage (Vth) of a PMOS transistor, the saturated current (Ids) of the PMOS transistor and the non-silicide resistance of a PD region is measured as the electrical properties of the semiconductor devices.

7. The manufacturing method for a semiconductor device according to claim 1, wherein the impurities are impurities which are doped into source and drain regions of the semiconductor devices.

8. The manufacturing method for a semiconductor device according to claim 1, wherein the thermal annealing is RTA (rapid thermal annealing) that is carried out in a rapid thermal annealing apparatus.

9. The manufacturing method for a semiconductor device according to claim 4, wherein the constant value is no higher than 20° C.

10. The manufacturing method for a semiconductor device according to claim 1, wherein the thermal annealing is carried out between 900° C. to 1200° C.

11. A rapid thermal annealing apparatus, comprising a stage for supporting a wafer, a heat source for heating said wafer for each zone, a thermometer for measuring the temperature of said wafer for each zone, a temperature controller for taking in temperature information from said thermometer and calculating the output value of said heat source for each zone, a driver for making said heat source output for each zone in accordance with the set output value from said temperature controller, and a process control system for providing data on temperature distribution which indicates temperature distribution within a wafer surface at the time of thermal annealing and is the control target for said wafer for each zone to said temperature controller, wherein said process control system expects inconsistency in the electrical property values of the finally gained semiconductor devices within a wafer surface, and generates temperature distribution data showing the temperature distribution within a wafer surface so that the inconsistency in the electrical property values of said semiconductor devices within the wafer surface becomes minimal as the temperature distribution data showing the temperature distribution within the wafer surface at the time of said thermal annealing process on the basis of the distribution of physical quantities within the wafer surface which have a correlation with the electrical property values of the semiconductor devices and are gained during the manufacturing process for said semiconductor devices, and data on temperature distribution within the wafer surface which is gained from the equipment management data of a thermal annealing apparatus that is used to activate impurities after the doping of the impurities, and thereby, temperature distribution within a wafer surface which makes inconsistency in the electrical property values of said semiconductor devices within the wafer surface minimal in the thermal annealing process for activating impurities after the doping of the impurities is gained.

12. The rapid thermal annealing apparatus according to claim 11, wherein
an expected value that is gained as a result of expectation of inconsistency of the electrical property values of said semiconductor devices within the wafer surface is converted to a table of temperature offset within the wafer surface for correcting the inconsistency of the electrical property values of said semiconductor devices within the wafer surface, and
said data on temperature distribution showing temperature distribution within the wafer surface at the time of said thermal annealing is determined on the basis of said table of the temperature offset within the wafer surface and the data on temperature distribution within the wafer surface that is gained from the equipment management data of said thermal annealing apparatus.

13. The rapid thermal annealing apparatus according to claim 11, wherein said temperature controller carries out electrical property measurement on the semiconductor devices after the thermal annealing process, calculates the temperature distribution within the wafer surface from the difference between said measurement results and the designed value of the electrical properties of said semiconductor devices, and controls the output value of said heat source so as to correct the temperature distribution.

14. The rapid thermal annealing apparatus according to claim 11, wherein the physical quantities are measured values which are gained through measurement of size or measurement of film thickness, which are carried out in order to confirm how processing was carried out after the processing during the manufacturing process.

15. The rapid thermal annealing apparatus according to claim 11, wherein the impurities are impurities which are doped into source and drain regions of the semiconductor devices.

16. The rapid thermal annealing apparatus according to claim 11, wherein the thermal annealing is carried out between 900° C. to 1200° C.

17. The rapid thermal annealing apparatus according to claim 11, wherein the heat source for heating a wafer is a lamp having a wavelength ranging from visible to infrared.

18. The rapid thermal annealing apparatus according to claim 11, wherein the thermometer for measuring the temperature of a wafer is a non-contact type pyrometer that is installed on the rear surface of the wafer, or a thermocouple that makes contact with the rear surface of the wafer.

19. The rapid thermal annealing apparatus according to claim 11, wherein a heat source which is placed on the front surface of a wafer and a thermometer which is placed on the rear surface of the wafer correspond one-to-one through a temperature controller for taking in information from said thermometer and calculating the output value of said heat source, and through a driver for making said heat source output.

20. The rapid thermal annealing apparatus according to claim 19, wherein said heat source and said thermometer share the same alignment, and said thermometer is placed directly beneath said heat source.

21. The rapid thermal annealing apparatus according to claim 19, wherein the wafer does not rotate.
